(19) United States
(12) Patent Application Publication
(10) Pub. No.: US 2022/0384451 A1
(43) Pub. Date: Dec. 1, 2022

(54) MEMORY STRUCTURE AND MEMORY LAYOUT

(71) Applicant: Changxin Memory Technologies, Inc., Hefei City (CN)

(72) Inventors: Yang Zhao, Hefei City (CN); Jaeyong Cha, Hefei City (CN)

(21) Appl. No.: 17/661,321

(22) Filed: Apr. 29, 2022

(30) Foreign Application Priority Data
May 31, 2021 (CN) 202110601628.7

(51) Int. Cl. H01L 27/108; G11C 11/4091; G11C 11/4096

(52) U.S. Cl. CPC H01L 27/10897; G11C 11/4091; G11C 11/4096

(57) ABSTRACT

Embodiments of the present application provide a memory structure and a memory layout. The memory structure includes: memory arrays, each including memory cells; read-write conversion circuits, each disposed between two adjacent ones of the memory arrays in a first direction, the read-write conversion circuits being arranged in a second direction, having a symmetry axis in the second direction, and configured to write external data into the memory cells, or read data from the memory cells, and the first direction being perpendicular to the second direction; and sense amplification circuits, symmetrically disposed between two adjacent ones of the memory arrays based on the symmetry axis, and coupled to the memory cells in the adjacent ones of the memory arrays, configured to sense voltages of the memory cells and output logic 1 or 0 corresponding to the voltages of the memory cells.

### CROSS-REFERENCE TO RELATED APPLICATIONS

This application claims the priority of Chinese Patent Application No. 202110601628.7, submitted to the Chinese Intellectual Property Office on May 31, 2021, the disclosure of which is incorporated herein in its entirety by reference.

### TECHNICAL FIELD

The present disclosure relates to the field of semiconductor memory structure design, in particular to a memory structure and a memory layout.

### BACKGROUND

In a dynamic random access memory (DRAM), an operation of writing data into the memory is accomplished by storing charge into a capacitor of a memory cell, and an operation of reading data from the memory is accomplished by reading charge in the capacitor of the memory cell.

In the DRAM, the memory cell is connected to a bit line (BL) and a complementary bit line (BLB). During the data readout operation, a sense amplifier in the readout circuit is configured to read a voltage of the BL and a voltage of the BLB, and amplify a voltage difference between the bit line BL and the complementary bit line BLB.

However, the applicant found that corresponding metal-oxide-silicon (MOS) transistors in different sense amplifiers have different device characteristics due to inconsistent device environments around them. Further, the device characteristics of the corresponding MOS transistors in the different sense amplifiers need to be matched with one another. That is, the corresponding MOS transistors in the different sense amplifiers having different device characteristics affects an overall amplification capability of the sense amplifiers, thereby reducing performance of the DRAM.

### SUMMARY

An embodiment of the present disclosure provide a memory structure, including: memory arrays, each including a plurality of memory cells; read-write conversion circuits, each disposed between two adjacent ones of the memory arrays in a first direction, the read-write conversion circuits being arranged in a second direction, having a symmetry axis in the second direction, and configured to write external data into the memory cells, or read data from the memory cells, and the first direction being perpendicular to the second direction; and sense amplification circuits, symmetrically disposed between two adjacent ones of the memory arrays based on the symmetry axis, coupled to the memory cells in the adjacent ones of the memory arrays, and configured to sense voltages of the memory cells and output logic 1 or 0 corresponding to the voltages of the memory cells; where, extension directions of gate structures of MOS transistors in each of the sense amplification circuits are the same as extension directions of gate structures of MOS transistors in each of the read-write conversion circuits.

An embodiment of the present disclosure further provides a memory layout, including: memory array layouts; read-write conversion circuit layouts, each disposed between two adjacent ones of the memory array layouts in a first direction, the read-write conversion circuit layouts being arranged in a second direction, and having a symmetry axis in the second direction, and the first direction being perpendicular to the second direction; and sense amplification circuit layouts, symmetrically disposed between two adjacent ones of the memory array layouts based on the symmetry axis; where, extension directions of gate patterns in each of the sense amplification circuit layouts are the same as extension directions of gate patterns in each of the read-write conversion circuit layouts.

### BRIEF DESCRIPTION OF THE DRAWINGS

FIG. 1 is a schematic structural diagram of a memory according to the present disclosure.

FIG. 2 is a schematic structural diagram of a memory structure according to an embodiment of the present disclosure.

FIG. 3 to FIG. 5 are schematic structural diagrams of a read-write conversion circuit according to an embodiment of the present disclosure.

FIG. 6 is a schematic diagram of a layout manner of a memory structure according to an embodiment of the present disclosure.

FIG. 7 is a schematic diagram of a layout manner of a read-write conversion circuit according to an embodiment of the present disclosure.

FIG. 8 and FIG. 9 are schematic structural diagrams of a memory layout according to another embodiment of the present disclosure.

### DETAILED DESCRIPTION

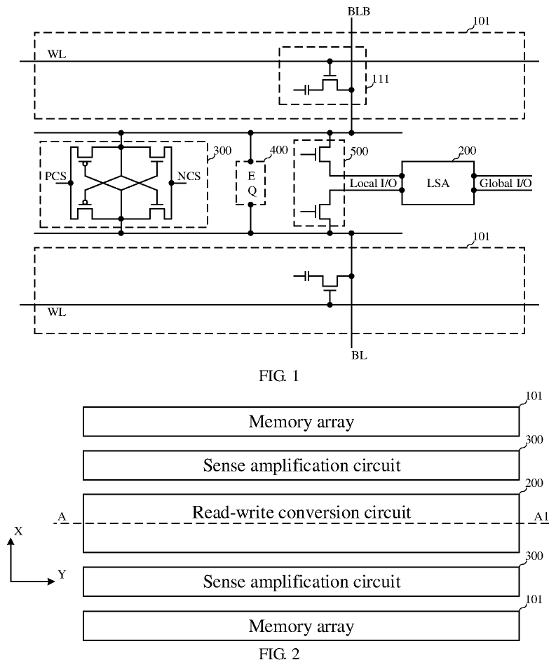

Referring to FIG. 1, in a memory structure, each memory array 101 includes a plurality of memory cells 111. A memory cell 111 is a one-transistor-one-capacitor (1T1C) structure constituted by a cell transistor and a cell capacitor. A read-write conversion circuit 200, a sense amplification circuit 300, an equalization circuit 400, and an input/output circuit 500 are disposed between adjacent memory arrays.

One terminal of a source and a drain of the cell transistor is connected to the cell capacitor, and the other terminal is connected to a bit line BL/complementary bit line BLB. A word line WL is connected to a gate of the cell transistor, and is configured to selectively turn on the gate of the corresponding cell transistor, so as to connect the cell capacitor with the bit line BL/complementary bit line BLB. In this way, an electrical signal in the bit line BL/complementary bit line BLB is written into the cell capacitor, or an electrical signal in the cell capacitor is read to the bit line BL/complementary bit line BLB.

The equalization circuit 400 is connected to the bit line BL and the complementary bit line BLB, and is configured to equalize voltages of the bit line BL and the complementary bit line BLB in a pre-charge stage.

The input/output circuit 500 includes: an input/output transistor. One terminal of a source and a drain of the input/output transistor is connected to the bit line BL/complementary bit line BLB, and the other terminal is connected to a local data line Local I/O. A gate is configured to receive a selection signal, and, according to the selection signal, selectively turn on the bit line BL/complementary bit line BLB corresponding to the selection signal, so as to connect the bit line BL/complementary bit line BLB with the local data line Local I/O, thereby realizing data transfer between the bit line BL/complementary bit line BLB and the local data line Local I/O.

The local data line Local I/O is connected to a global data line Global I/O via the read-write conversion circuit 200, so as to transmit external data or data in the local sense amplifier (disposed in the read-write conversion circuit 200) to the local data line Local I/O, or output data in the local data line Local I/O to the global data line Global I/O.

The sense amplification circuit 300 is connected between the bit line BL and the complementary bit line BLB. In a case that the electrical signal in the cell capacitor is read to the bit line BL/complementary bit line BLB, the voltage of the bit line BL/complementary bit line BLB is increased or decreased by a voltage variation AV from a pre-charge voltage, due to charge sharing between the cell capacitor and the bit line BL/complementary bit line BLB. The sense amplification circuit 300 is configured to response to readout of a first control signal PCS and a second control signal NCS, and amplify the voltage variation AV between the bit line BL and the complementary bit line BLB.

During an amplification operation of the sense amplification circuits 300, the corresponding MOS transistors in the different sense amplifiers have different device characteristics due to inconsistent device environments around them. However, the device characteristics of the corresponding MOS transistors in the different sense amplifiers need to be matched with one another. That is, the corresponding MOS transistors in the different sense amplifiers having different device characteristics affects an overall amplification capability of the sense amplifiers, thereby reducing the performance of the DRAM.

In order to solve the above technical problem, an embodiment of the present disclosure provides a memory structure, including: memory arrays, each including a plurality of memory cells; read-write conversion circuits, each disposed between two adjacent ones of the memory arrays in a first direction, the read-write conversion circuits being arranged in a second direction, having a symmetry axis in the second direction, and configured to write external data into the memory cells, or read data from the memory cells, and the first direction being perpendicular to the second direction; and sense amplification circuits, symmetrically disposed between two adjacent ones of the memory arrays based on the symmetry axis, coupled to the memory cells in the adjacent ones of the memory arrays, and configured to sense voltages of the memory cells and output logic 1 or 0 corresponding to the voltages of the memory cells. Extension directions of gate structures of MOS transistors in each of the sense amplification circuits are the same as extension directions of gate structures of MOS transistors in each of the read-write conversion circuits.

In order to make the objectives, technical solutions and advantages of the embodiments of the present disclosure clearer, the embodiments of the present disclosure are described below with reference to the accompanying drawings. Those of ordinary skill in the art should understand that many technical details are proposed in each embodiment of the present disclosure to help the reader better understand the present disclosure. However, even without these technical details and various changes and modifications made based on the following embodiments, the technical solutions claimed in the present disclosure may still be realized. The following divisions of the various embodiments are intended for convenience of description, and are not intended to constitute any limitation to the specific implementation of the present disclosure. The various embodiments may be combined with each other in case of no contradiction.

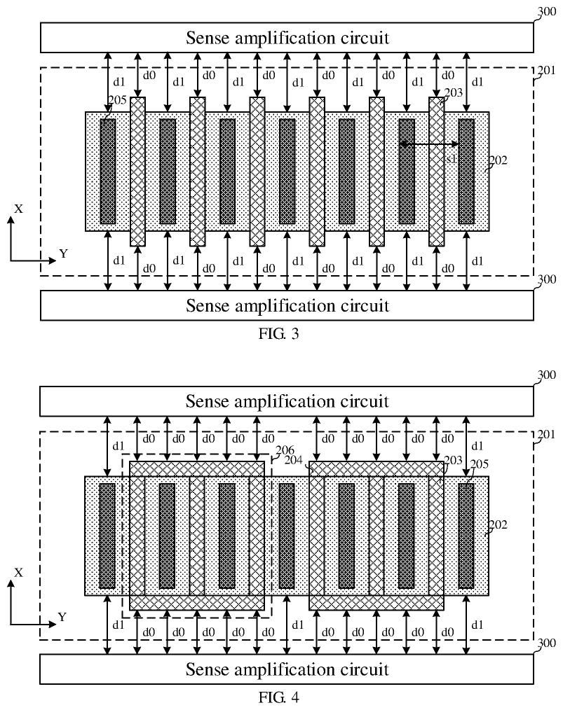

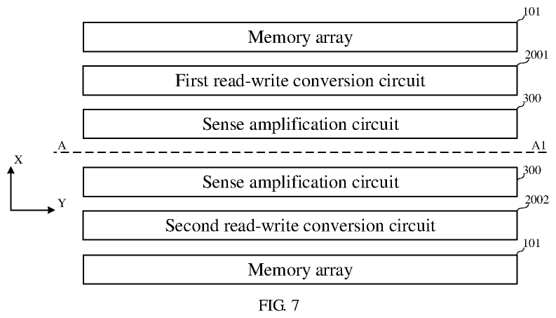

FIG. 2 is a schematic structural diagram of a memory structure according to this embodiment, FIG. 3 to FIG. 5 are schematic structural diagrams of a read-write conversion circuit according to this embodiment, FIG. 6 is a schematic diagram of a layout manner of a memory structure according to this embodiment, and FIG. 7 is a schematic diagram of a layout manner of a read-write conversion circuit according to an embodiment. The following details the memory structure according to this embodiment with reference to the accompanying drawings, specifically as follows:

Referring to FIG. 2, the memory structure includes:

Memory arrays 101, each memory array 101 including a plurality of memory cells 111 (referring to FIG. 1).

A read-write conversion circuit 200, disposed between two adjacent memory arrays 101 in a first direction X. The read-write conversion circuit is arranged in a second direction Y, and has a symmetry axis AA1 in the second direction. The read-write conversion circuit 200 is configured to write external data into the memory cells 111 (referring to FIG. 1), or read data of the memory cells 111. The first direction X and the second direction Y are perpendicular to each other.

It should be noted that, the “external data” in this embodiment includes, but is not limited to, data in the global data line Global I/O (referring to FIG. 1) and in a local sense amplifier (referring to FIG. 1, disposed in the read-write conversion circuit 200).

Sense amplification circuits 300, symmetrically disposed between two adjacent memory arrays 101 based on the symmetry axis AA1, coupled to the memory cells 111 (referring to FIG. 1) in the adjacent ones of the memory arrays 101, and are configured to sense voltages of the memory cells 111 (referring to FIG. 1) and output logic 1 or 0 corresponding to the memory cells 111 (referring to FIG. 1). Gate structures of MOS transistors in the sense amplification circuits 300 have the same extension direction as gate structures of MOS transistors in the read-write conversion circuit 200. The sense amplification circuits 300 are disposed based on the symmetry axis AA1 of the read-write conversion circuit 200. That is, the corresponding MOS transistors in the different sense amplifiers are disposed based on the symmetry axis AA1 of the read-write conversion circuit 200, to allow the environments of the corresponding MOS transistors in the sense amplification circuits 300 that are disposed on two sides of the read-write conversion circuit 200 to be consistent with one another, thereby ensuring consistent device characteristics of the different sense amplifiers.

It should be noted that, in gaps between adjacent memory arrays 101, the read-write conversion circuits 200 and the sense amplification circuits 300 are arranged in the second direction Y. That is, a plurality of read-write conversion circuits 200 and sense amplification circuits 300 are arranged in the second direction Y.

In this embodiment, as an example, the MOS transistors in the read-write conversion circuit 200 are N-channel metal-oxide semiconductor (NMOS) transistors, which, however, does not constitute a limitation on this embodiment. In other embodiments, the MOS transistors in the read-write conversion circuit may be P-channel metal-oxide semiconductor (PMOS) transistors.

In some embodiments, referring to FIG. 3, each of the MOS transistors in the read-write conversion circuit 200 includes:

an active area 202, disposed in a well region 201 of a semiconductor substrate, and extending in the second direction Y.

In some embodiments, in the first direction X, distances between active areas of the MOS transistors in the sense amplification circuits 300 adjacent to the MOS transistors in the read-write conversion circuit 200 and the active area 202 are equal. In some embodiments, the distances between the active area 202 and the active areas in the sense amplification circuits 300 on two sides are d1. In addition, a distance between any edge position of the active area 202 and the active area in the sense amplification circuit 300 on either side is equal.

Gate structures 203, disposed on the active area 202 at intervals, and extending in the first direction X.

In some embodiments, distances between the gate structures 203 and gate structures in the sense amplification circuits 300 on two sides are d0. In addition, in the first direction X, distances between upper edge positions of the gate structures 203 and lower edge positions of the gate structures in an upper sense amplification circuit 300 are equal, and distances between lower edge positions of the gate structures 203 and upper edge positions of the gate structures in a lower sense amplification circuit 300 are equal. Intervals s1 between adjacent gate structures 203 that are disposed at intervals are equal. The gate structures 203 are spaced apart at equal distances on the active area 202, to ensure that the sense amplified circuits on two sides of the read-write conversion circuit have consistent environments. It should be noted that, in this embodiment, the “environment” consistency refers to that surrounding semiconductor structures made of the same material have the same characteristics in terms of size, distance, and arrangement.

The gate structures 203 of the read-write conversion circuit 200 extend in the first direction. In addition, the read-write conversion circuit 200 has the symmetry axis AA1 in the second direction Y. The extension directions of the gate structures 203 of the MOS transistors in the read-write conversion circuit 200 are consistent with the extension directions of the gate structures of the MOS transistors in the sense amplification circuits 300, which further ensures that the distances between the gate structures of the corresponding MOS transistors in the sense amplification circuits 300 on two sides of the read-write conversion circuit 200 and the gate structures 203 of the MOS transistors in the read-write conversion circuit 200 are equal. This equalizes the device characteristics of the sense amplifiers on two sides of each read-write conversion circuit 200, thereby improving yield of the DRAM.

Conductive contact structures 205, disposed on the active area 202 in gaps between two adjacent gate structures 203. Heights of top surfaces of the conductive contact structures 205 are higher than heights of top surfaces of the gate structures 203. The active area 202 on two ends of the gate structures 203 are respectively used as sources and drains of the MOS transistors. One ends of the conductive contact structures 205 are electrically connected to the active area 202 on two sides of the gate structures 203, and the other ends are configured to export signals of the active area 202.

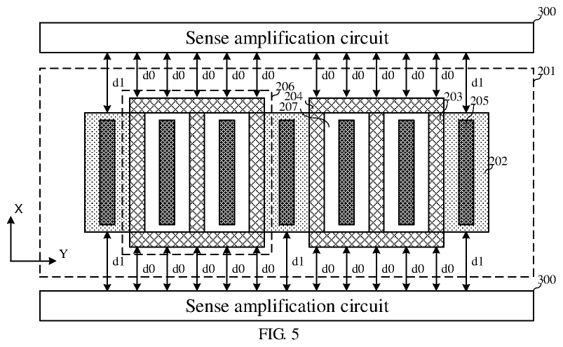

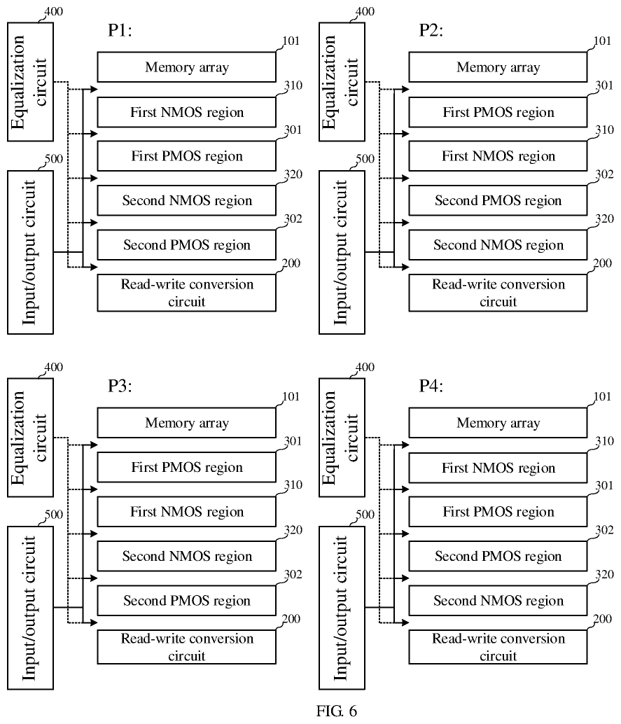

Further, referring to FIG. 4 and FIG. 5, in this embodiment, each of the MOS transistors in the read-write conversion circuit 200 further includes:

Gate extension structures 204, disposed on edges of the gate structures 203 on the active area 202, and extending in the second direction Y. The gate extension structures 204 and the gate structures 203 form ring-shaped gate structures 206. In the first direction X, distances d0 between the gate structures of the MOS transistors in the sense amplification circuits 300 adjacent to the gate extension structures 204 and the gate extension structures 204 are equal. By forming the gate extension structures 204 at the edges of the gate structures 203, the gate extension structures 204 and the gate structures 203 together form the ring-shaped gate structures 206. The gate extension structures 204 extend in the second direction Y. That is, the gate extension structures 204 are disposed in parallel with the adjacent sense amplification circuits 300, to ensure that the distances between the gate structures of the MOS transistors in the sense amplification circuit 300 and the gate extension structures 204 are equal.

In this embodiment, the gate extension structures 204 and the gate structures 203 are made of a same material. Heights of top surfaces of the gate extension structures 204 are consistent with heights of top surfaces of the gate structures 203. Thicknesses of the gate extension structures 204 are consistent with thicknesses of the gate structures 203. By ensuring that the gate extension structures 204 and the gate structures 203 have the same material, consistent thicknesses and heights, the gate extension structures 204 and the gate structures 203 may be formed in the same process step.

In this embodiment, the conductive contact structures 205 and the gate extension structures 204 are insulated from each other.

In an example, referring to FIG. 4, the conductive contact structures 205 extend in the first direction X, and are in no contact with the ring-shaped gate structures 206. By separately arranging the conductive contact structures 205 and the ring-shaped gate structures 206, the conductive contact structures 205 and the gate extension structures 204 are insulated from each other.

In another example, referring to FIG. 5, the read-write conversion circuit 200 further includes: isolation structures 207, disposed on inner sidewalls of the ring-shaped gate structures 206. The conductive contact structures 205 fill remaining voids of the ring-shaped gate structures 206, so that the conductive contact structures 205 and the gate extension structures 204 are insulated from each other by the isolation structures 207.

Referring to FIG. 6, in this embodiment, the sense amplification circuit 300 includes:

a circuit of a first NMOS region 310, coupled to the memory cells 111 (referring to FIG. 1) in the adjacent memory array 101; a circuit of a second NMOS region 320, coupled to the memory cells 111 in the adjacent memory array 101; a circuit of a first PMOS region 301, coupled to the memory cells 111 in the adjacent memory array 101; and a circuit of a second PMOS region 302, coupled to the memory cells 111 in the adjacent memory array 101. The circuits of the first NMOS regions 310 in the sense amplification circuits 300 on two sides of the read-write conversion circuit 200 are symmetrically disposed based on the symmetry axis AA1; the circuits of the second NMOS regions 320 in the sense amplification circuits 300 on two sides of the read-write conversion circuit 200 are symmetrically disposed based on the symmetry axis AA1; the circuits of the first PMOS regions 301 in the sense amplification circuits 300 on two sides of the read-write conversion circuit 200 are symmetrically disposed based on the symmetry axis AA1; and the circuits of the second PMOS regions 302 in the sense amplification circuits 300 on two sides of the read-write conversion circuit 200 are symmetrically disposed based on the symmetry axis AA1.

The sense amplification circuits 300 further include: equalization circuits 400, symmetrically disposed between two adjacent memory arrays 101 based on the symmetry axis AA1, and electrically connected to the sense amplification circuits 300, for balancing voltages of lines, wherein each of the lines is between one sense amplification circuit 300 and one memory cell 111 coupled to the sense amplification circuit 300 (referring to FIG. 1); and input/output circuits 500, symmetrically disposed between two adjacent memory arrays 101 based on the symmetry axis AA1, and electrically connected to the memory cells 111 of the adjacent ones of the memory arrays 101, for selecting the memory cells 111 in the memory arrays 101. In a case of performing a write operation, the memory transmits the data on the local data line Local I/O to the bit line BL, and then writes the data into the memory cells 111; in a case of performing a read operation, the memory transfers the data on the bit line BL to the local data line Local I/O, thereby reading out the data from the memory.

In a case of lay outing the sense amplification circuits 300, the equalization circuits 400, the input/output circuits 500, and the read-write conversion circuit 200, the read-write conversion circuit 200 is disposed in a middle of the gap between two adjacent memory arrays 101, and the read-write conversion circuit 200 has the symmetry axis AA1. The circuits of the first NMOS regions 310, the circuits of the second NMOS regions 320, the circuits of the first PMOS regions 301, the circuits of the second PMOS regions 302, the equalization circuits 400, and the input/output circuits 500 are symmetrically disposed on two sides of the read-write conversion circuit 200 based on the symmetry axis AA1, respectively.

In some embodiments, in a layout manner, referring to the layout manners shown as P1 and P2 in FIG. 6, a circuit of the first NMOS region 310, a circuit of the second NMOS region 320, a circuit of the first PMOS region 301 and a circuit of the second PMOS region 302 are alternately arranged on one side of the read-write conversion circuit 200. The equalization circuit 400 and the input/output circuit 500 may be located at any position between the circuit of the first NMOS region 310, the circuit of the second NMOS region 320, the circuit of the first PMOS region 301 and the circuit of the second PMOS region 302. The equalization circuit 400 disposed on the same side is served as the equalization circuit 400 for one sense amplification circuit 300 (referring to FIG. 1).

In a layout manner, referring to the layout manners shown as P3 and P4 in FIG. 6, the circuit of the first NMOS region 310 and the circuit of the second NMOS region 320 are located between the circuit of the first PMOS region 301 and the circuit of the second PMOS region 302, or the circuit of the first PMOS region 301 and the circuit of the second PMOS region 302 are located between the circuit of the first NMOS region 310 and the circuit of the second NMOS region 320. The equalization circuit 400 and the input/output circuit 500 may be located at any position between the circuit of the first NMOS region 310, the circuit of the second NMOS region 320, the circuit of the first PMOS region 301 and the circuit of the second PMOS region 302. The equalization circuit 400 on the same side is served as the equalization circuit 400 for one sense amplification circuit 300 (referring to FIG. 1).

It should be noted that, the layout manners shown in FIG. 6 merely illustrate exemplary layouts of the sense amplification circuit 300 on one side of the read-write conversion circuit 200. The sense amplification circuit on the other side of the read-write conversion circuit 200 is arranged symmetrically with respect to the shown sense amplification circuit 300 based on the symmetry axis AA1.

In addition, referring to FIG. 7, the read-write conversion circuit 200 (referring to FIG. 2) includes a first read-write conversion circuit 2001 and a second read-write conversion circuit 2002. The first read-write conversion circuit 2001 and the second read-write conversion circuit 2002 are disposed close to the memory arrays 101. In addition, the first read-write conversion circuit 2001 and the second read-write conversion circuit 2002 are symmetrically disposed.

In some embodiments, the first read-write conversion circuit 2001 is disposed between the sense amplification circuit 300 and the memory array 101, and the second read-write conversion circuit 2002 is arranged between the sense amplification circuit 300 and the memory array 101. The first read-write conversion circuit 2001 and the second read-write conversion circuit 2002 are symmetrically disposed based on the symmetry axis AA1. That is, the read-write conversion circuit (referring to FIG. 2) constituted by the first read-write conversion circuit 2001 and the second read-write conversion circuit 2002 has the symmetry axis AA1.

It should be noted that, in the embodiment as shown in FIG. 7, the first read-write conversion circuit 2001 and the second read-write conversion circuit 2002 are disposed between the sense amplification circuits 300 and the memory arrays 101. In other embodiments, the first read-write conversion circuit and the second read-write conversion circuit may be disposed in the sense amplification circuits 300, and symmetrically disposed based on the symmetry axis AA1.

Compared with the related art, the gate structures of the read-write conversion circuit in the present disclosure extend in the first direction, and the read-write conversion circuit has the symmetry axis in the second direction. The sense amplification circuits are symmetrically disposed based on the symmetry axis of the read-write conversion circuit. That is, the MOS transistors in the different sense amplification circuits are symmetrically disposed based on the symmetry axis of the read-write conversion circuit, to ensure that the environments of the corresponding MOS transistors in the different sense amplification circuits disposed on two sides of the read-write conversion circuit are consistent with one another. In addition, the extension directions of the gate structures of the MOS transistors in the read-write conversion circuits are consistent with the extension directions of the gate structures of the MOS transistors in the sense amplification circuits, which further ensures that the distances between the gate structures of the corresponding MOS transistors in the different sense amplification circuits on two sides of the read-write conversion circuit and the gate structures of the MOS transistors in the read-write conversion circuit are equal. This balances the device characteristics of the corresponding MOS transistors in the different sense amplifiers, thereby improving the stability of the DRAM.

Another embodiment of the present disclosure also provides a memory layout, including: a memory array layout; a read-write conversion circuit layout, disposed between two adjacent memory array layouts in a first direction, the read-write conversion circuit layout being arranged in a second direction, and having a symmetry axis in the second direction, and the first direction being perpendicular to the second direction; sense amplification circuit layouts, symmetrically disposed between two adjacent memory array layouts based on the symmetry axis. Extension directions of gate patterns in the sense amplification circuit layouts are the same as extension directions of gate patterns in the read-write conversion circuit layouts.

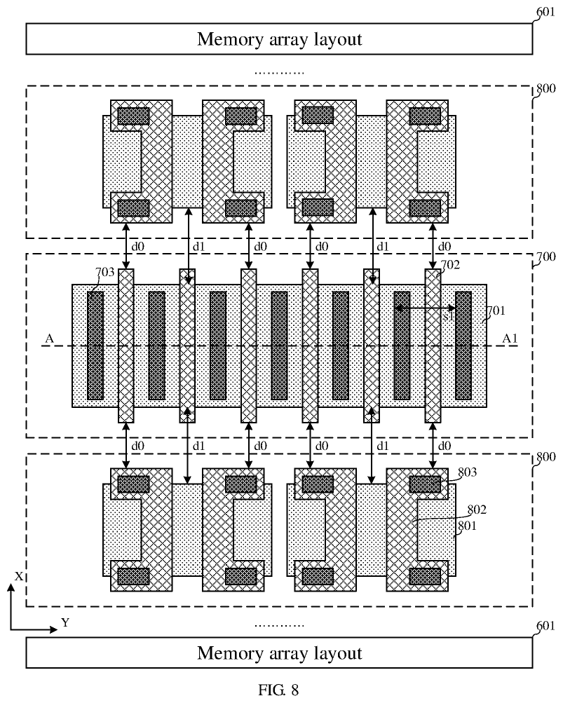

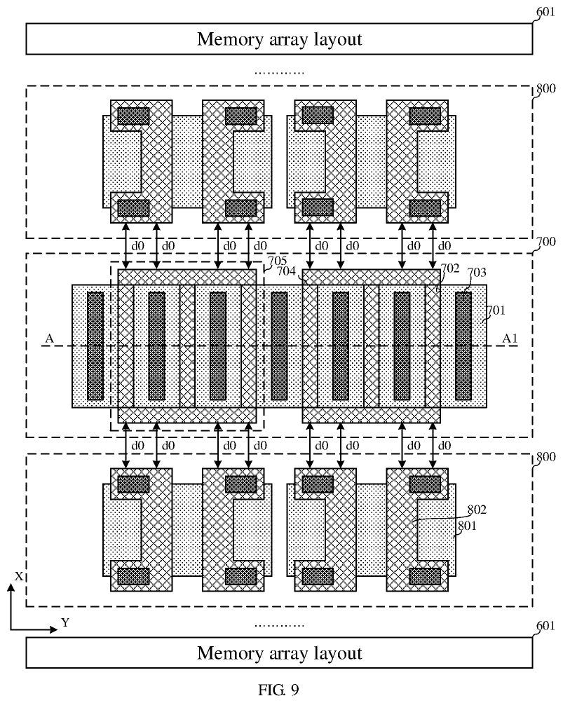

FIG. 8 and FIG. 9 are schematic structural diagrams of a memory layout according to this embodiment. The following details the memory layout according to the embodiment with reference to the accompanying drawings, specifically as follows:

Referring to FIG. 8 and FIG. 9, the memory layout includes:

Memory array layouts 601, extending in a second direction Y, and the memory array layouts 601 being configured to form the memory arrays 101 (referring to FIG. 1).

A read-write conversion circuit layout 700, disposed between two adjacent memory array layouts 601 in a first direction X. The read-write conversion circuit layout 700 is arranged in the second direction Y, and has a symmetry axis AA1 in the second direction Y. The first direction X is perpendicular to the second direction Y. The read-write conversion circuit layout 700 is configured to form the read-write conversion circuit 200 (referring to FIG. 1).

Sense amplification circuit layouts 800, symmetrically disposed between two adjacent memory array layouts 601 based on the symmetry axis AA1. Extension directions of gate patterns 802 in the sense amplification circuit layouts 800 are the same as extension directions of gate patterns 702 in the read-write conversion circuit layout 700.

It should be noted that, FIG. 8 and FIG. 9 do not illustrate structures of equalization circuit layouts and input/output circuit layouts. It will be appreciated that, based on the foregoing embodiments, in an embodiment, the memory layout further includes: equalization circuit layouts, disposed between two adjacent memory array layouts 601 based on the symmetry axis AA1, and configured to form the equalization circuits 400 (referring to FIG. 1); and input/output circuit layouts, disposed between two adjacent memory array layouts 601 based on the symmetry axis AA1, and configured to form the input/output circuits 500 (referring to FIG. 1).

Specific referring to FIG. 8, the read-write conversion circuit layout 700 includes:

an active pattern 701, disposed in a well region 201 (referring to FIG. 3) of a semiconductor substrate, extending in the second direction Y, and configured to form the active area 202 (referring to FIG. 3).

In some embodiments, in the first direction X, distances between active patterns 801 of the MOS transistors in the sense amplification circuit layouts 800 adjacent to the MOS transistors in the read-write conversion circuit layout 700 and the active pattern 701 are equal. In some embodiments, the distances between the active pattern 701 and the active pattern 801 in the sense amplification circuit layout 800 on either side is dl. In addition, a distance between any edge position of the active pattern 701 and the active pattern 801 in the sense amplification circuit layout 800 on either side is equal.

Gate patterns 702, disposed on the active pattern 701 at intervals, extending in the first direction X, and configured to form the gate structures 203 (referring to FIG. 3).

In some embodiments, distances between the gate patterns 702 and the gate patterns 802 in the sense amplification circuit layouts 800 on two sides are d0, and

distances between upper edge positions of the gate patterns 702 and lower edge positions of the gate patterns 802 in an upper sense amplification circuit layout 800 are equal, and distances between lower edge positions of the gate patterns 702 and upper edge positions of the gate patterns 802 in a lower sense amplification circuit layout 800 are equal. Intervals s1 between adjacent ones of the gate patterns 702 that are disposed at intervals are equal. Conductive contact patterns 703, disposed on the active pattern 701 in gaps between two adjacent gate patterns 702, and configured to form the conductive contact structures 205 (referring to FIG. 3).

Further, referring to FIG. 9, in this embodiment, each of the MOS transistors in the read-write conversion circuit layout 700 further includes:

Gate extension patterns 704, disposed on edges of the gate patterns 702 on the active pattern 701, extending in the second direction Y, and configured to form the gate extension structures 204 (referring to FIG. 4 and FIG. 5). The gate extension patterns 704 and the gate patterns 702 form closed rings 705. In the first direction X, distances between the gate patterns of the MOS transistors in the sense amplification circuit layouts 800 adjacent to the gate extension patterns 704 and the gate extension patterns 704 are equal.

In this embodiment, the gate extension patterns 704 and the gate patterns 702 are made of a same material. By ensuring that the gate extension patterns 704 and the gate patterns 702 have consistent materials, the gate extension patterns 704 and the gate patterns 702 may be formed in the same process step.

In this embodiment, the conductive contact patterns 703 and the gate extension patterns 704 are arranged to be insulated from each other.

In an example, referring to FIG. 9, the conductive contact patterns 703 extend in the first direction X, and are in no contact with the closed rings 705. By separately arranging the conductive contact patterns 703 and the closed rings 705, the conductive contact structures 205 (referring to FIG. 3) subsequently formed by the conductive contact patterns 703 and the gate extension structures 204 (referring to FIG. 4 and FIG. 5) formed by the gate extension patterns 704 are insulated from each other.

In another example, the read-write conversion circuit layout 700 further includes isolation patterns, disposed on inner sidewalls of the closed rings. The conductive contact patterns fill remaining voids of the closed rings, so that the conductive contact patterns 703 and the gate extension patterns 704 are insulated from each other by the isolation patterns, to form the read-write conversion circuit 200 (referring to FIG. 1) as shown in FIG. 5.

In addition, in this embodiment, the sense amplification circuit layout 800 includes: a first NMOS region layout, a second NMOS region layout, a first PMOS region layout, and a second PMOS region layout. The first NMOS region layout and the second PMOS region layout are disposed between two adjacent memory array layouts 601 based on the symmetry axis AA1. The first PMOS region layout and the second PMOS region layout are disposed between two adjacent memory array layouts 601 based on the symmetry axis AA1. The first NMOS region layout is configured to form the circuit of the first NMOS region 310 (referring to FIG. 6), the second NMOS region layout is configured to form the circuit of the second NMOS region 320 (referring to FIG. 6), the first PMOS region layout is configured to form the circuit of the first PMOS region 301 (referring to FIG. 6), and the second PMOS region layout is configured to form the circuit of the second PMOS region 302 (referring to FIG. 6), so as to form the memory structure as shown in FIG. 6 by the corresponding layout manner of the memory.

Compared with the related art, the gate patterns of the read-write conversion circuit layout in the present disclosure extend in the first direction, and the read-write conversion circuit layout has the symmetry axis in the second direction. The sense amplification circuit layouts are symmetrically disposed based on the symmetry axis of the read-write conversion circuit layout. That is, the MOS transistors in the different sense amplification circuit layouts are symmetrically disposed based on the symmetry axis of the read-write conversion circuit layout, to ensure that the environments of the corresponding MOS transistors in the different sense amplification circuit layouts on two sides of the read-write conversion circuit layout are consistent with one another. In addition, the extension directions of the gate patterns of the MOS transistors in the read-write conversion circuit layout are consistent with the extension directions of the gate patterns of the MOS transistors in the sense amplification circuit layouts, which further ensures that the distances between the gate patterns of the corresponding MOS transistors in the different sense amplification circuit layouts on two sides of the read-write conversion circuit layout and the gate patterns of the MOS transistors in the read-write conversion circuit layout are equal. This balances the device characteristics of the corresponding MOS transistors in the different sense amplifiers, thereby improving the stability of the DRAM.

Since the first embodiment corresponds to this embodiment, this embodiment may be implemented in cooperation with the first embodiment. The related technical details mentioned in the first embodiment are still valid in this embodiment, and the technical effects that may be achieved in the first embodiment may also be achieved in this embodiment, which will not be repeated here. Correspondingly, the related technical details mentioned in this embodiment may also be applied to the first embodiment.

Those of ordinary skill in the art should understand that the above embodiments are specific embodiments for implementing the present disclosure. In practical applications, various changes may be made to the above embodiments in terms of form and details without departing from the spirit and scope of the present disclosure.

1. A memory structure, comprising:
memory arrays, each of the memory arrays comprising a plurality of memory cells;
read-write conversion circuits, each of the read-write conversion circuits disposed between two adjacent ones of the memory arrays in a first direction; the read-write conversion circuits being arranged in a second direction, having a symmetry axis in the second direction, and configured to write external data into the memory cells, or read data from the memory cells; and the first direction being perpendicular to the second direction; and
sense amplification circuits, symmetrically disposed between two adjacent ones of the memory arrays based on the symmetry axis, coupled to the memory cells in the adjacent ones of the memory arrays, and configured to sense voltages of the memory cells and output logic 1 or 0 corresponding to the voltages of the memory cells;
wherein, extension directions of gate structures of metal-oxide-silicon transistors in each of the sense amplification circuits are the same as extension directions of gate structures of metal-oxide-silicon transistors in each of the read-write conversion circuits.

2. The memory structure according to claim 1, wherein each of the metal-oxide-silicon transistors in the read-write conversion circuits comprises:
an active area, disposed in a well region of a semiconductor substrate, and extending in the second direction;
the gate structures, disposed on the active area at intervals, and extending in the first direction; and
conductive contact structures, disposed on the active area in gaps between two adjacent ones of the gate structures, and heights of top surfaces of the conductive contact structures being higher than heights of top surfaces of the gate structures.

3. The memory structure according to claim 2, wherein spacings between every two adjacent ones of the gate structures that are disposed at intervals are the same.

4. The memory structure according to claim 2, wherein each of the metal-oxide-silicon transistors in the read-write conversion circuits further comprises:
gate extension structures, disposed on edges of the gate structures on the active area, extending in the second direction, and forming ring-shaped gate structures together with the gate structures;
wherein in the first direction, distances between the gate structures of the metal-oxide-silicon transistors in the sense amplification circuits adjacent to the gate extension structures and the gate extension structures are equal.

5. The memory structure according to claim 2, wherein in the first direction, distances between active areas of the metal-oxide-silicon transistors in the sense amplification circuits adjacent to one of the read-write conversion circuits and the active area of the metal-oxide-silicon transistor in the read-write conversion circuit are equal.

6. The memory structure according to claim 4, wherein a material of the gate extension structures is the same as a material of the gate structures, heights of top surfaces of the gate extension structures are consistent with heights of top surfaces of the gate structures, and thicknesses of the gate extension structures are consistent with thicknesses of the gate structures.

7. The memory structure according to claim 4, wherein the conductive contact structures extend in the first direction, and the conductive contact structures are in no contact with the ring-shaped gate structures.

8. The memory structure according to claim 4, wherein the read-write conversion circuits each further comprises:
isolation structures, disposed on inner sidewalls of the ring-shaped gate structures;
wherein the conductive contact structures fill remaining voids of the ring-shaped gate structures.

9. The memory structure according to claim 1, wherein each of the sense amplification circuits comprises:
a circuit of a first N-channel metal-oxide semiconductor region, coupled to the memory cells in the adjacent one of the memory arrays;
a circuit of a second N-channel metal-oxide semiconductor region, coupled to the memory cells in the adjacent one of the memory arrays;
a circuit of a first P-channel metal-oxide semiconductor region, coupled to the memory cells in the adjacent one of the memory arrays; and
a circuit of a second P-channel metal-oxide semiconductor region, coupled to the memory cells in the adjacent one of the memory arrays.

10. The memory structure according to claim 1, further comprising:
equalization circuits, symmetrically disposed between two adjacent ones of the memory arrays based on the symmetry axis, electrically connected to the sense amplification circuits, and configured to equalize voltages of lines; wherein each of the lines is between a sense amplification circuit and a the memory cell coupled to the sense amplification circuit; and
input/output circuits, symmetrically disposed between two adjacent ones of the memory arrays based on the symmetry axis, electrically connected to the memory cells in the adjacent ones of the memory arrays, and configured to select the memory cells in the memory arrays.

11. A memory layout, comprising:
memory array layouts;
read-write conversion circuit layouts, each of the read-write conversion circuit layouts disposed between two adjacent ones of the memory array layouts in a first direction; the read-write conversion circuit layouts being arranged in a second direction, having a symmetry axis in the second direction; and the first direction being perpendicular to the second direction; and
sense amplification circuit layouts, symmetrically disposed between two adjacent ones of the memory array layouts based on the symmetry axis;
wherein, extension directions of gate patterns in the sense amplification circuit layouts are the same as extension directions of gate patterns in the read-write conversion circuit layouts.

12. The memory layout according to claim 11, wherein the read-write conversion circuit layouts each comprises:
an active pattern, disposed in a well region of a semiconductor substrate, and extending in the second direction;
the gate patterns, disposed on the active pattern at intervals, and extending in the first direction; and
conductive contact patterns, disposed on the active pattern in gaps between two adjacent ones of the gate patterns.

13. The memory layout according to claim 12, wherein spacings between every two adjacent ones of the gate patterns that are disposed at intervals are the same.

14. The memory layout according to claim 12, wherein the read-write conversion circuit layouts each further comprises:
gate extension patterns, disposed on edges of the gate patterns on the active pattern, extending in the second direction, and forming closed rings together with the gate patterns;
wherein in the first direction, distances between the gate patterns in the sense amplification circuit layouts adjacent to the gate extension patterns and the gate extension patterns are equal.

15. The memory layout according to claim 12, wherein in the first direction, distances between active patterns in the sense amplification circuit layouts adjacent to the active pattern in the read-write conversion circuit layout and the active pattern in the read-write conversion circuit layout are equal.

16. The memory layout according to claim 14, wherein the conductive contact patterns extend in the first direction, and the conductive contact patterns are in no contact with the closed rings.

17. The memory layout according to claim 11, wherein each of the sense amplification circuit layouts comprises: a first N-channel metal-oxide semiconductor region layout, a second N-channel metal-oxide semiconductor region layout, a first P-channel metal-oxide semiconductor region layout, and a second P-channel metal-oxide semiconductor region layout.

18. The memory layout according to claim 11, further comprising:
equalization circuit layouts, symmetrically disposed between two adjacent ones of the memory array layouts based on the symmetry axis; and
input/output circuit layouts, symmetrically disposed between two adjacent ones of the memory array layouts based on the symmetry axis.
